(19) United States
(12) Patent Application Publication
(10) Pub. No.: US 2020/0006544 A1
(43) Pub. Date: Jan. 2, 2020

(54) SEMICONDUCTOR DEVICE INCLUDING SILICON CARBIDE BODY AND TRANSISTOR CELLS

(71) Applicant: Infineon Technologies AG, Neubiberg (DE)

(72) Inventors: Ralf SIEMIENIEC, Villach (AT); Thomas AICHINGER, Faak am See (AT); Wolfgang BERGNER, Klagenfurt (AT); Romain ESTEVE, Prisdorf (DE); Daniel KUECK, Villach (AT); Dethard PETERS, Hoechstadt (DE); Bernd ZIPPELIUS, Erlangen (DE)

(21) Appl. No.: 16/454,752

(22) Filed: Jun. 27, 2019

(30) Foreign Application Priority Data
Jun. 29, 2018 (DE) 102018115728.2

(51) Int. Cl. H01L 29/78; H01L 29/16

(52) U.S. Cl. CPC H01L 29/782; H01L 29/1608

(57) ABSTRACT

A semiconductor device includes a silicon carbide body including a transistor cell region and an idle region. The transistor cell region includes transistor cells. The idle region is devoid of transistor cells. The idle region includes a transition region between the transistor cell region and a side surface of the silicon carbide body, a gate pad region, and a diode structure comprising at least one of a merged pin Schottky diode structure or a merged pin heterojunction diode structure in at least one of the transition region or the gate pad region.

### RELATED APPLICATION

This application claims priority to German Patent Application No. 102018115728.2, filed on Jun. 29, 2018, entitled “SEMICONDUCTOR DEVICE INCLUDING SILICON CARBIDE BODY AND TRANSISTOR CELLS”, which is incorporated herein.

### TECHNICAL FIELD

The present disclosure is related to semiconductor devices, in particular, to silicon carbide semiconductor devices with transistor cells.

### BACKGROUND

Semiconductor devices including field effect transistor cells include pn junctions between a drift zone and body regions of the field effect transistor cells. The pn junctions form an intrinsic body diode. When the body diode is biased in forward direction, a bipolar current of electrons and holes passes the drift zone and the body regions. The forward voltage drop across the body diode and electrical losses caused by the body diode result from parameters, e.g., dimensions of doped regions and dopant concentrations in doped regions, which are typically selected in view of the desired properties of the field effect transistor cells.

There is a need to improve semiconductor devices based on silicon carbide.

### SUMMARY

An embodiment of the present disclosure relates to a semiconductor device that includes a silicon carbide body including a transistor cell region and an idle region. The transistor cell region includes transistor cells. The idle region is devoid of transistor cells and includes a transition region between the transistor cell region and a side surface of the silicon carbide body, a gate pad region, and a diode structure comprising at least one of a merged pin Schottky diode structure or a merged pin heterojunction diode structure in at least one of the transition region or the gate pad region.

Another embodiment of the present disclosure relates to a semiconductor device that includes a silicon carbide body including a central region and a transition region. The central region includes a transistor cell region and a gate pad region. The transistor cell region includes transistor cells. The transition region is devoid of transistor cells, is positioned between the central region and a side surface of the silicon carbide body and includes a junction structure. The junction structure includes a Schottky contact or a heterojunction.

A further embodiment of the present disclosure relates to a semiconductor device including a silicon carbide body that includes a transistor cell region and an idle region. The transistor cell region includes transistor cells. The idle region is devoid of transistor cells and includes a transition region between the transistor cell region and a side surface of the silicon carbide body, a gate pad region, and a junction structure in at least one of the transition region or the gate pad region, wherein the junction structure includes a Schottky contact or a heterojunction.

### BRIEF DESCRIPTION OF THE DRAWINGS

The accompanying drawings are included to provide a further understanding the embodiments and are incorporated in and constitute a part of this specification. The drawings illustrate the embodiments of the semiconductor device and the method of manufacturing a semiconductor device and together with the description serve to explain principles of the embodiments. Further embodiments are described in the following detailed description and the claims.

FIGS. 1A-1B illustrate schematic plan and cross-sectional views of a semiconductor device including a diode structure comprising at least one of a merged pin Schottky diode structure or a merged pin heterojunction diode structure in at least one of a gate pad region or a transition region according to an embodiment.

FIGS. 2A-2B illustrate schematic horizontal and vertical cross-sectional views of a semiconductor device including a merged pin Schottky diode structure in a gate pad region according to an embodiment.

FIGS. 3A-3B illustrate schematic horizontal and vertical cross-sectional views of a semiconductor device including a merged pin heterojunction diode structure in a gate pad region according to another embodiment.

FIGS. 4A-4B illustrate schematic horizontal and vertical cross-sectional views of a semiconductor device including a merged pin Schottky diode structure in a gate pad region according to another embodiment.

FIGS. 5A-5B illustrate schematic horizontal and vertical cross-sectional views of a semiconductor device including a merged pin heterojunction diode structure below a gate wiring line according to another embodiment.

FIGS. 6A-6B illustrate schematic horizontal and vertical cross-sectional views of a semiconductor device including a merged pin Schottky diode structure below a gate wiring line according to another embodiment.

FIGS. 7A-7B illustrate schematic horizontal and vertical cross-sectional views of a semiconductor device including a merged pin Schottky diode structure below a source wiring line in a transition region according to another embodiment.

FIGS. 8A-8B illustrate schematic horizontal and vertical cross-sectional views of a semiconductor device including a merged pin Schottky diode structure below a source wiring line in a transition region according to a further embodiment.

FIG. 9 illustrates a schematic plan view of a semiconductor device with a gate pad region greater than a gate pad according to an embodiment.

FIG. 10 illustrates a schematic plan view of a semiconductor device according to an embodiment with a junction structure formed in a transition region.

FIGS. 11A-11B illustrate schematic horizontal and vertical cross-sectional views of a semiconductor device with a heterojunction structure below a gate wiring line according to another embodiment.

FIGS. 12A-12B illustrate schematic horizontal and vertical cross-sectional views of a semiconductor device with a Schottky contact below a source wiring line according to a further embodiment.

FIG. 13 illustrates a schematic plan view of a semiconductor device according to an embodiment related to a junction structure in at least one of a gate pad region or a transition region.

### DETAILED DESCRIPTION

In the following detailed description, reference is made to the accompanying drawings, which form a part thereof and in which are shown by way of illustrations specific embodiments in which a semiconductor device may be practiced. It is to be understood that other embodiments may be utilized and structural or logical changes may be made without departing from the scope of the present disclosure. For example, features illustrated or described for one embodiment can be used on or in conjunction with other embodiments to yield yet a further embodiment. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be between the electrically coupled elements, for example, elements that are controllable to temporarily provide a low-resistive connection in a first state and a high-resistive electric decoupling in a second state.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

Two adjoining doping regions of the same conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa.

Ranges given for physical dimensions include the boundary values. For example, a range for a parameter y from a to b reads as a≤y≤b. A parameter y with a value of at least c reads as c≤y and a parameter y with a value of at most d reads as y≤d.

A safe operating area (SOA) defines voltage and current conditions over which a semiconductor device can be expected to operate without self-damage. The SOA is given by published maximum values for device parameters like maximum continuous load current, maximum gate voltage and others.

IGFETs (insulated gate field effect transistor) are voltage controlled devices including MOSFETs (metal oxide semiconductor FETs) and other FETs with gate electrodes based on doped semiconductor material and/or with gate dielectrics that are not or not exclusively based on an oxide.

According to an embodiment a semiconductor device may include a silicon carbide body that may include a transistor cell region and an idle region. The transistor cell region may include transistor cells. The idle region may be devoid of transistor cells and may include at least one of: a transition region between the transistor cell region and a side surface of the silicon carbide body, a gate pad region, or a diode structure comprising at least one of a merged pin Schottky diode structure or a merged pin heterojunction diode structure in at least one of the transition region or the gate pad region.

The gate pad region includes at least a portion of the silicon carbide body directly below a gate pad. A gate pad is a compact metal structure with sufficient mechanical strength to facilitate wire bonding or sintering of a metal clip on a top surface of the gate pad. The gate pad region may further include a portion of the silicon carbide body directly below a gap between the gate pad and a source pad. The gate pad region may be between the transistor cell region and the transition region or the transistor cell region may surround the gate pad region.

An outline of the transistor cell region is given by a line or by two lines connecting the outermost transistor cells of the transistor cell region, wherein the outermost transistor cells are those one with the smallest distance to the side surface and/or to the gate pad. The transistor cell region may include other elements in addition to the transistor cells.

Both a merged PiN Schottky (MPS) diode structure and a merged PiN heterojunction (MPH) diode structure may include a pn junction. An MPS diode structure and a contact material may form a main junction and an ohmic contact, and an MPH diode structure and a contact material may form a main junction and an ohmic contact.

The contact material and a diode region in the silicon carbide body may form the main junction. In an MPS diode structure the contact material has no band gap, i.e. is a conductor. In an MPH diode structure the contact material has a band gap that differs from a band gap of the diode region. A shielding region in the silicon carbide body and the diode region may form the pn junction. The shielding region and the contact material, or the shielding region and another material electrically connected with the contact material may form the ohmic contact.

The merged diode structure may behave like a Schottky diode or like a heterojunction diode in a forward-biased state and like a pn diode in a reverse biased state. The merged pin Schottky diode structure and the merged pin heterojunction diode structure show a lower forward voltage drop than an intrinsic bipolar body diode of the semiconductor device. For example, the forward voltage drop across a pn junction in silicon carbide may be between 2.5 V and 3 V and the forward voltage drop across a Schottky contact in silicon carbide may be lower than 2 V, e.g., lower than 1.5 V at the same forward current and at the same temperature.

The diode structure comprising at least one of the merged pin Schottky diode structure or the merged pin heterojunction diode structure may significantly reduce turn-on losses, reverse-recovery losses and thermal stress in the semiconductor device. DC/DC converters that use, e.g., the semiconductor device as power switch in a rectification stage may show higher efficiency.

Both the Schottky contact and the heterojunction may provide an unipolar charge carrier flow containing only one type of charge carriers, i.e., electrons or holes, such that the current through the merged diode structure does not cause bipolar degradation. Since the Schottky contact and/or the heterojunction may bypass the internal body diode for the complete SOA, bipolar degradation can be effectively reduced or avoided.

The diode structure comprising at least one of the merged pin Schottky diode structure or the merged pin heterojunction diode structure outside the transistor cell region may be formed without affecting area efficiency of the semiconductor device.

According to an embodiment the semiconductor device may include a contact layer formed on a first surface of the silicon carbide body. The diode structure may include a doped diode region and a doped shielding region. The shielding region and the doped region may form a pn junction. The contact layer and the doped diode region may form a Schottky contact or a heterojunction. The contact layer and the shielding region may form an ohmic contact. A dopant concentration in the diode regions is sufficiently low such that the diode region and the contact layer do not form an ohmic contact. A laterally integrated dopant concentration in the diode region is lower than a breakdown charge per area of silicon carbide divided by the elementary charge. The diode region may be fully depletable.

At Schottky contacts, Schottky barrier lowering at the metal-semiconductor junction may lead to a comparatively high leakage current through the Schottky contact under reverse bias. The presence of the shielding regions may reduce the effective electric field at the metal-semiconductor junction. Depletion regions extending from the pn junction into the diode region may pinch-off a leakage current through the Schottky contact. The diode structure may combine the low forward voltage drop and low switching losses of Schottky diodes with the low leakage current of pn diodes.

According to an embodiment the diode structure may be formed in the gate pad region. The area of the gate pad region may be more than 10% of the area of the transistor cell region such that in the gate pad region a comparatively large diode structure can be implemented without affecting the area efficiency of the semiconductor device.

According to an embodiment the semiconductor device may include a junction termination region that surrounds and/or defines the transistor cell region. A lateral extension of the junction termination region may define an inner transition area. The diode structure may be formed in the inner transition area.

The lateral extension of the junction termination region is defined orthogonal to a transition between the transistor cell region and the transition region.

The inner transistor area may be a portion of the transition region directly adjoining the transistor region. An outer transition area may separate the inner transition area from the side surface. A pn junction may be formed at a transition between inner and outer transition area, wherein the outer transition area may be connected to a drain potential and the inner transition area may be connected to a source potential.

The diode structure may be formed in the inner transition area. The lateral extension of the junction termination region is a width of the junction termination region measured perpendicular to a boundary line between the transistor cell region and the transition region. The junction termination region may have a uniform width along the complete circumferential line around the transistor cell region.

The junction termination region may have the conductivity type of the shielding region. The junction termination region may include differently doped portions. For example, the junction termination region may include a more lightly doped portion and a more heavily doped portion between the more lightly doped portion and the transistor cell region.

Portions of the junction termination region may be effective as the shielding regions of the MPS and/or MPH (MPS/MPH) diode structures such that the MPS/MPH diode structures may be formed without increasing process complexity.

According to an embodiment the junction termination region may include rail portions and rung portions, wherein each rail portion may surround the transistor cell region and each rung portion may connect neighboring rail portions. The rail portions and the rung portions may be effectively used as shielding regions for the MPS/MPH diode structure such that the MPS/MPH diode structure may be formed without significantly increasing process complexity.

According to an embodiment the semiconductor device may include a gate wiring line that may be formed on a first surface of the silicon carbide body in the inner transition area. An interlayer dielectric may separate the gate wiring line and the contact layer. The MPS/MPH diode structure below the gate wiring line may be formed without affecting area efficiency of the semiconductor device.

According to an embodiment the semiconductor device may include a source wiring line that may be formed on a first surface of the silicon carbide body in the inner transition area. The MPS/MPH diode structure below the source wiring line may be formed without affecting area efficiency of the semiconductor device.

According to another embodiment a semiconductor device may include a silicon carbide body that may include a central region and a transition region. The central region may include a transistor cell region and a gate pad region. The transistor cell region may include transistor cells. The transition region may be devoid of transistor cells. The transition region is positioned between the central region and a side surface of the silicon carbide body and includes a junction structure. The junction structure may include a Schottky contact or a heterojunction.

The lower forward voltage drop of a Schottky contact or a heterojunction compared to the voltage drop across the intrinsic body diode of the transistor cells may result in that the Schottky contact or the heterojunction bypasses the internal body diode for an operation of the semiconductor device within the SOA. The Schottky contact and/or the heterojunction may avoid bipolar degradation and/or may reduce electric losses in the reverse biased mode of the semiconductor device. For a given size of the silicon carbide body the Schottky contact and/or the heterojunction can be formed without reducing the area of the transistor cell region such that the Schottky contact and/or the heterojunction have no adverse impact on other device parameters and/or area efficiency.

According to an embodiment the semiconductor device may include a contact layer formed on a first surface of the silicon carbide body. The junction structure may include a doped diode region. The contact layer and the diode region may form the Schottky contact or the heterojunction.

According to an embodiment the semiconductor device may include a junction termination region that surrounds the central region. A lateral extension of the junction termination region may define an inner transition area. The junction structure may be formed in the inner transition area without affecting area efficiency.

According to an embodiment the semiconductor device may include a gate wiring line formed on a first surface of the silicon carbide body in the inner transition area. An interlayer dielectric may be formed between the gate wiring line and the junction structure. The junction structure can be formed below the gate wiring line without affecting area efficiency.

According to an embodiment the semiconductor device may include a source wiring line formed on a first surface of the silicon carbide body in the inner transition area. The contact layer of the junction structure may be formed from a portion of the source wiring line. The Schottky contact can be formed without reducing area efficiency.

According to another embodiment a semiconductor device may include a silicon carbide body that may include a transistor cell region and an idle region. The transistor cell region may include transistor cells. The idle region may be devoid of transistor cells and may include a transition region between the transistor cell region and a side surface of the silicon carbide body, a gate pad region, and a junction structure in at least one of the transition region or the gate pad region. The junction structure may include a Schottky contact or a heterojunction.

According to an embodiment the junction structure may be positioned in a transition region, wherein the junction structure may be formed without reducing area efficiency.

According to an embodiment the junction structure may include a heterojunction, wherein a contact layer of the junction structure may be formed contemporaneously with, e.g., gate electrodes of transistor cells.

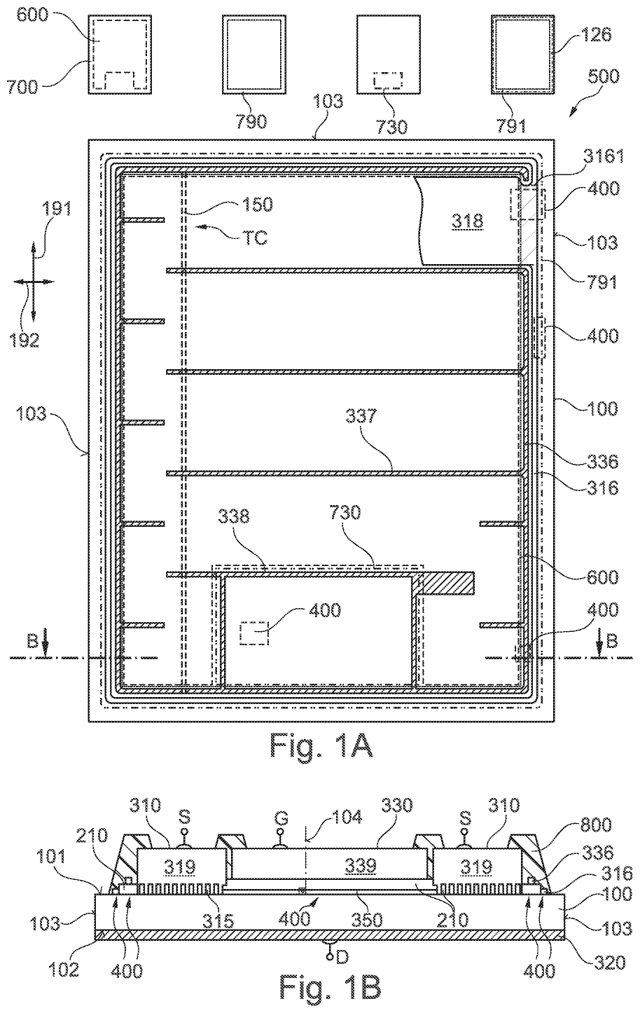

The semiconductor device 500 shown in FIGS. 1A and 1B may be or may include a RC-IGBT (reverse-conducting insulated gate bipolar transistor), an MCD (MOS controlled diode), a JFET (junction field effect transistor) or an IGFET, for example, a MOSFET, by way of example.

FIG. 1A illustrates plan views of a front side of a silicon carbide body 100 of the same semiconductor device 500, wherein each of the four small pictograms at the top of FIG. 1A illustrates at least one of various regions of the silicon carbide body 100. Source pad 319, gate pad 339, passivation layer 800 and interlayer dielectric 210, which are illustrated in the vertical cross-section of FIG. 1B, are omitted in FIG. 1A for clarity.

The silicon carbide body 100 may include a silicon carbide crystal with the main constituents silicon and carbon. The silicon carbide crystal may include unwanted impurities like hydrogen and oxygen and/or intended impurities, e.g., dopant atoms. The polytype of the silicon carbide crystal may be 2H, 6H, 15R or 4H, by way of example.

A first surface 101 at the front side of the silicon carbide body 100 may be planar or ripped. A second surface 102 at the backside of the silicon carbide body 100 is parallel to the first surface 101. A side surface 103 connects the first surface 101 and the second surface 102. A surface normal 104 onto a planar first surface 101 or onto a mean plane of a ripped first surface 101 defines a vertical direction. Directions orthogonal to the surface normal 104 are horizontal and lateral directions. A horizontal cross-sectional area of the silicon carbide body 100 may form a rectangle.

The silicon carbide body 100 includes a transistor cell region 600 with transistor cells TC and an idle region 700 without transistor cells TC. The transistor cells TC are operational transistor cells that can be turned on and off. In the on-state each transistor cell TC conducts a portion of a load current that vertically flows through the silicon carbide body 100. In the off-state the transistor cells TC block a load current flow. The transistor cell region 600 includes an intrinsic body diode.

The transistor cells TC may be stripe-shaped and may extend along a first horizontal direction 191 from one side of the transistor cell region 600 to the opposite side. The transistor cell region 600 may include a plurality of transistor cells TC that may extend parallel to each other.

The idle region 700 is devoid of operational transistor cells. The idle region 700 and the transistor cell region 600 may complement each other to the complete silicon carbide body 100.

The idle region 700 may include a gate pad region 730 and a transition region 790. The gate pad region 730 includes at least a portion of the silicon carbide body 100 defined by a vertical projection of a gate pad 339 into the silicon carbide body 100 and may include a further portion of the silicon carbide body 100 directly adjoining the vertical projection of the gate pad 339.

The transition region 790 may separate the transistor cell region 600 from a side surface 103 of the silicon carbide body 100. The transition region 790 may form a rectangular frame around the transistor cell region 600 and the gate pad region 730. A junction termination region 126 that surrounds the transistor cell region 600 may be formed in an inner transition area 791, which forms an innermost portion of the transition region 790.

A front side metallization formed at the front side on and/or above the silicon carbide body 100 may include a gate metallization 330 and a source metallization 310. The gate metallization 330 may include various metal structures and layers electrically connected or coupled to each other and to a gate terminal G. The source metallization may include various metal structures and layers electrically connected to each other and to a source terminal S. A drain electrode 320 may be formed along the second surface 102 and may form or may be electrically connected to a drain terminal D.

The front side metallization may include a thin fine-patterned portion and a thick coarse-patterned portion.

The coarse-patterned portion may be comparatively thick, e.g., at least several micrometers. Minimum edge lengths of coarse-patterned structures and minimum distances between different coarse-patterned structures may be in a range of several 10 micrometers. Structures of the coarse-patterned portion may form stable bases for bonding wires and/or to sintering metal clips on a top surface of the coarse-patterned portion. The coarse-patterned portion may include or consist of at least one of copper (Cu), copper aluminum alloy (CuAl), or copper silicon aluminum alloy (CuSiAl).

The coarse-patterned portion of the gate metallization 330 may include a gate pad 339 above the gate pad region 730 of the silicon carbide body 100. A portion of an interlayer dielectric 210 may be formed between the gate pad 339 and the silicon carbide body 100. A further conductive structure 350 may be formed between the interlayer dielectric 210 and the silicon carbide body 100. The conductive structure 350 may include heavily doped polycrystalline silicon and may be electrically connected to the source metallization 310 or to the gate metallization 330.

The coarse-patterned portion of the source metallization 310 may include a source pad 319 above the transistor cell region 600 of the silicon carbide body 100. Portions of the interlayer dielectric 210 may be formed between gate electrodes of the transistor cells TC and the source pad 319. Contact structures 315 extending through the interlayer dielectric 210 may electrically connect the source pad 319 with doped regions of the transistor cells TC.

The fine-patterned portion of the front side metallization may be comparatively thin, e.g., in the range of few 100 nanometers. Minimum edge lengths of fine-patterned structures and minimum distances between different fine-patterned structures may be in a range of few 100 nanometers. The fine-patterned portion may connect the coarse-patterned portion of the front side metallization with the transistor cells TC.

The fine-patterned portion of the front side metallization may include portions of at least a first layer, wherein the first layer may include, by way of example, at least one of a titanium (Ti) layer, a titanium nitride (TiN) layer, a tantalum (Ta) layer, a tantalum nitride (TaN) layer or a tungsten (W) portion. The fine-patterned portion may further include portions of a second layer formed on the first layer, wherein the second layer may include a high conductive material, e.g. aluminum (Al).

In the illustrated example, the fine-patterned portion of the gate metallization 330 may include gate wiring lines 336, 337, 338. For example, a gate runner 336 may be formed above the inner transition area 791 and may form a closed frame or an open frame around the central transistor cell region 600. Gate fingers 337 may extend from the gate runners 336 into the transistor cell region 600, where the gate fingers 337 may be electrically connected to gate electrodes of the transistor cells. Further gate wiring lines 338 may be formed in the gate pad region 730 and/or may extend from the gate pad region 730 into neighboring portions of the transistor cell region 600.

The gate wiring lines 336, 337, 338 may be formed at a distance to the first surface 101 of the silicon carbide body 100. Portions of the interlayer dielectric 210 may be formed between the gate wiring lines 336, 337, 338 and the silicon carbide body 100.

The fine-patterned portion of the source metallization 310 may include an interface layer 318 and a source wiring line 316, by way of example. The interface layer 318 may be in direct contact with doped regions of the transistor cells TC in the transistor cell region 600. For example, the interface layer 318 may be formed in contact fields defined between the gate fingers 337 and the gate runner 336. In FIG. 1A the interface layer 318 is omitted in the contact fields. The interface layer 318 may form at least portions of the contact structures 315 extending in the transistor cell region 600 through the interlayer dielectric 210 down to or into the silicon carbide body 100.

The source wiring line 316 may surround the transistor cell region 600. For example, the source wiring line 316 may form a frame around the transistor cell region 600. The source wiring line 316 may be formed between the gate runner 336 and the side surface 103. The source wiring line 316 may be in direct contact with the junction termination extension 125. In the shaded area the source wiring line 316 may have a lateral bulge 3161 extending through an opening of a frame formed by the gate runner 336, such that the lateral bulge is in contact with the interface layer 318.

Diode structures 400 may be formed in at least one of the gate pad region 730, or the inner transition area 791. The diode structures 400 may extend across at least 50%, at least 90% or across the complete horizontal cross-sectional area of the gate pad region 730. In addition or alternatively, diode structures 400 may be formed at least along such portions of the inner transition area 791 that extend parallel to the transistor cells TC. The diode structures 400 may be formed at least on two opposite sides of the transistor cell region 600 and may extend along at least 50%, at least 90% or along 100% of the extension of the inner transition area 791 along the first horizontal direction 191. In addition or alternatively, diode structures 400 may be formed in the area of the lateral bulge of the source wiring line 316. The diode structures 400 may include at least one of MPS or MPH diode structures.

The diode structures 400 are electrically anti-parallel to the transistor cells TC and parallel to the intrinsic body diode in the transistor cell region 600. Due to their nature as MPS or MPH diode, the diode structures 400 set in at a lower reverse voltage than the body diode such that the body diode remains off as long as the semiconductor device 500 is in the SOA.

The diode structures 400 do not consume active area of the semiconductor device 500. Instead, inactive areas of the semiconductor device 500, which are typically used for wiring purposes, can be used to suppress a bipolar current through the intrinsic body diode and to reduce turn-on and reverse-recovery losses.

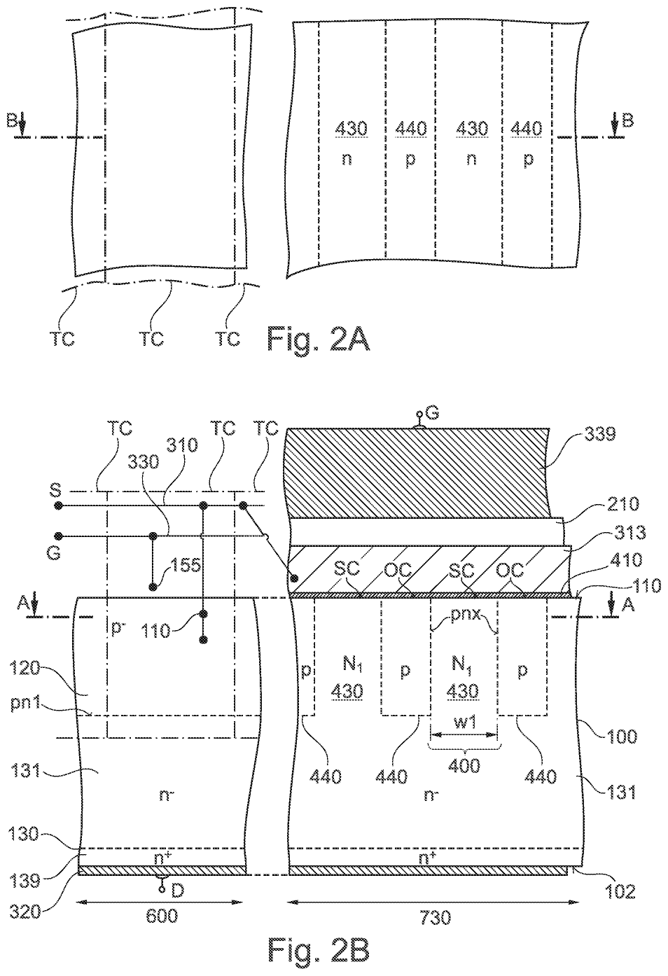

FIGS. 2A-2B show MPS diode structures 400 formed in a gate pad region 730 of a silicon carbide body 100.

The silicon carbide body 100 includes a drift structure 130 in contact with the second surface 102. The drift structure 130 may include a comparatively lightly doped drift zone 131 and a comparatively heavily doped contact portion 139 between the drift zone 131 and the second surface 102. Vertical extension of the drift zone 131 and dopant concentration in the drift zone 131 are selected such that the drift zone 131 can accommodate a predetermined blocking voltage.

Transistor cells TC are formed at a front side of the silicon carbide body 100 in a transistor cell region 600. The transistor cells TC may be transistor cells with lateral MOS channel and with planar gate structures formed on or a above a first surface 101 of the silicon carbide body 100 or may be transistor cells with vertical or tilted MOS channel and with trench gate structures extending from the first surface 101 into the silicon carbide body 100.

Each transistor cell TC may include a body region 120 and a source region 110, wherein the source region 110 may be formed between the first surface 101 and the body region 120 and wherein the body region 120 may be formed between the source region 110 and the drift structure 130. The body region 120 and the drift structure 130 form a first pn junction pn1.

In the illustrated embodiment the transistor cells TC are n-channel FET cells of the enhancement type, wherein the source region 110 and the drift zone 131 are n-doped and the body region 120 is p-doped. Other embodiments may refer to p-channel FETs and/or to transistor cells of the depletion type.

A source metallization 310 is electrically connected with the source region 110 and the body region 120 and may form or may be electrically connected or coupled to a source terminal S.

A drain electrode 320 may be formed along the second surface 102. The drain electrode 320 and the contact portion 139 may form an ohmic contact. The drain electrode 320 may form or may be electrically connected or coupled to a drain terminal D.

A plurality of transistor cells TC may be electrically connected in parallel between the source metallization 310 at the front side of the silicon carbide body 100 and the drain electrode 320 on the backside of the silicon carbide body 100. The first pn junctions pn1 of the transistor cells TC form an intrinsic body diode.

A gate metallization 330 may be electrically connected or coupled to gate electrodes 155 of the transistor cells TC. The gate metallization 330 may form or may be electrically connected or electrically coupled to a gate terminal G.

The gate pad region 730 includes a plurality of diode structures 400. At least some of the diode structures 400 may be formed in a vertical projection of a gate pad 339. The diode structures 400 may be stripe-shaped and may extend parallel to the transistor cells TC or orthogonal to the transistor cells TC, by way of example. Each diode structure 400 may include a diode region 430 of the conductivity type of the drift zone 131 and shielding regions 440 of the opposite conductivity type. A shielding region 440 between two neighboring diode structures 400 may be shared by the two neighboring diode structures 400.

The shielding regions 440 and the diode regions 430 form pn junctions pnx that may extend from the first surface 101 into the silicon carbide body 100. The pn junctions pnx may be vertical pn junctions orthogonal to the first surface 101 or tilted to the first surface 101 by an angle deviating from 90°. According to other embodiments, the pn junctions pnx may have bulges. A dopant concentration in the shielding regions 440 may be lower than, equal to, or higher than a dopant concentration in the body regions 120 at a same distance to the first surface 101.

A contact layer 410 may be formed directly on the first surface 101 in the gate pad region 730. The contact layer 410 may form Schottky contacts SC with the diode regions 430 and may form ohmic contacts OC with the shielding regions 440. The contact layer 410 may include one single layer.

For example, portions of the first layer of the fine-patterned metallization as described with reference to FIGS. 1A-2B may form the contact layer. The contact layer 410 may include or consist of Ti, TiN, Ta, TaN, W, Mo, MoN, Ni, NiAl, by way of example.

According to another embodiment the contact layer 410 may include at least two sublayers, wherein a first sublayer may be in direct contact with at least a greater portion of the diode regions 430 and wherein a second sublayer may be in direct contact with at least a greater portion of the shielding regions 440. For example, the first sublayer may be a patterned layer exclusively formed on the diode regions 430, wherein the second sublayer may alternatingly be formed on the first sublayer and on the first surface 101. Alternatively, the second sublayer may be exclusively formed on the shielding regions 440 and the first sublayer may alternatingly be formed on the first surface 101 and on the second sublayer. The first or the second sublayer may be formed from portions of the fine-patterned metallization as described with reference to FIGS. 1A-1B. The first and second sublayers may include at least one of Ti, TiN, Ta, TaN, W, Mo, MoN, Ni, or NiAl.

A source metallization 310 may include a connection layer 313 between the contact layer 410 and an interlayer dielectric 210, wherein a portion of the interlayer dielectric 210 is formed between the gate pad 339 and the connection layer 313 and electrically separates the gate pad 339 and the connection layer 313. The connection layer 313 may include, e.g., heavily doped polycrystalline silicon.

The diode structure 400 represents an MPS diode structure that has a lower set-in voltage than the intrinsic body diode formed by the first pn junctions pn1 in the transistor cell region 600. In the blocking mode, the shielding regions 440 reduce the electric field effective at the Schottky contacts SC and may pinch-off a leakage current through the diode regions 430. Dopant concentration N1 and a minimum lateral extension w1 of the diode regions 430 may be selected such that in each diode region 430 a lateral integral across the dopant concentration N1 is smaller than the breakdown charge of silicon carbide.

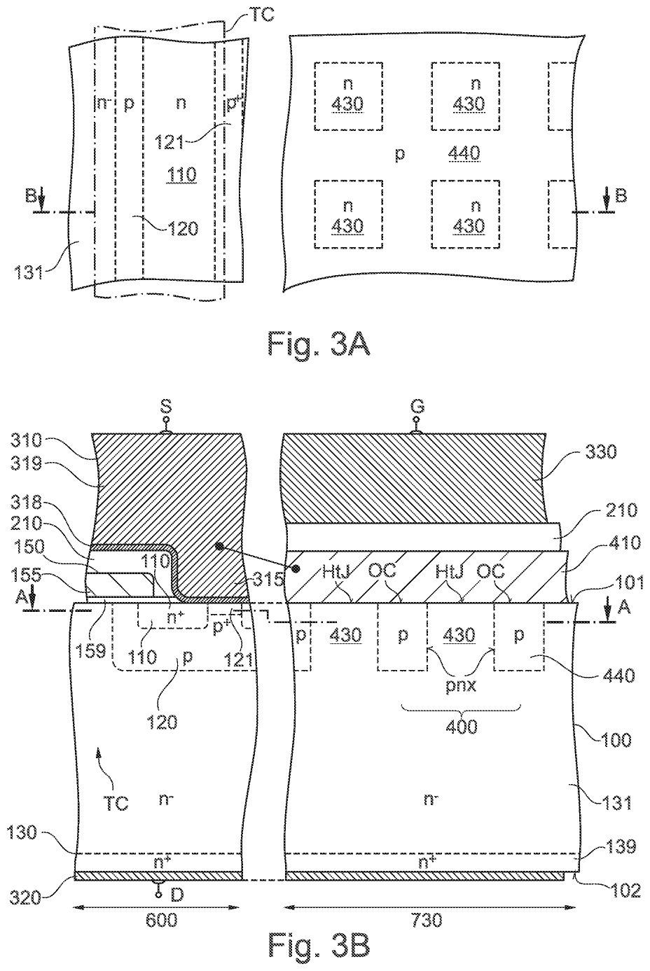

In FIGS. 3A-3B the contact layer 410 in the gate pad region 730 includes or consists of a semiconductor material with a bandgap that differs from the bandgap of the silicon carbide body 100. For example, the contact layer 410 may consist of or may include a heavily doped polycrystalline silicon layer, wherein the heavily doped polycrystalline silicon is in direct contact with the silicon carbide body 100. The contact layer 410 and the diode regions 430 may form heterojunctions HtJ. The contact layer 410, the diode region 430 and the shielding region 440 form a MPH diode structure 400, wherein the shielding regions 440 may reduce a leakage current through the diode region 430.

FIGS. 3A-3B further show an embodiment of a transistor cell region 600 with planar gate structures 150, wherein the gate structures 150 may include a gate dielectric 159 formed on the first surface 101 and a conductive gate electrode 155 formed on the gate dielectric 159. A portion of the interlayer dielectric 210 may separate the gate electrode 155 and a source metallization 310, wherein the source metallization 310 may include a source pad 319.

Below a central section of the gate structure 150 the drift structure 130, e.g., the drift zone 131 may extend up to the first surface 101 and may laterally separate two neighboring body regions 120. Source regions 110 of two neighboring transistor cells TC may be formed as wells extending from the first surface 101 into a body region 120 that may be shared by the two neighboring transistor cells TC. The body region 120 may include a more heavily doped body contact region 121 between the two source regions 110. Contact structures 315 may electrically connect the source regions 110 and body contact regions 121 with the source pad 319. For further details, reference is made to the description of the previous figures.

The body regions 120 in the transistor cell region 600 and the shielding regions 440 of the diode structures 400 may have a same vertical extension.

In the gate pad region 730 the shielding regions 440 of neighboring diode structures 400 may form a grid such that in a horizontal cross-section each diode region 430 may be surrounded by the grid-like shielding region 440. A lateral horizontal cross-sectional area of the diode regions 430 may be rectangular, for example, a square. Alternatively, the lateral horizontal cross-sectional areas of the diode regions 430 may be ovals or circles.

According to another embodiment, the diode regions 430 may be connected and may form a grid, wherein separated shielding regions 440 may be formed in the meshes of the grid.

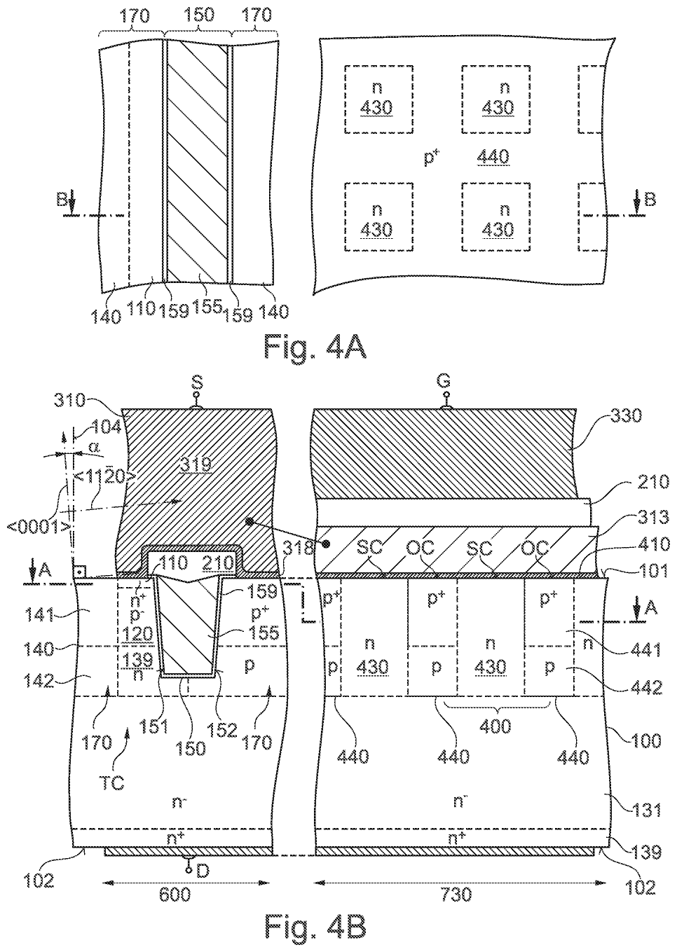

FIGS. 4A-4B illustrate another embodiment of an MPS diode structure in the gate pad region 730. In addition, FIGS. 4A-4B refer to an embodiment of a transistor cell region 600 that includes transistor cells TC with trench gate structures 150 with tilted sidewalls.

The silicon carbide body 100 may be from a hexagonal phase of silicon carbide, e.g., 4H—SiC. The <0001> crystal axis is tilted by an off-axis angle α to the surface normal 104. The <11-20> crystal axis is tilted by the off-axis angle α with respect to the horizontal plane. The <1-100> crystal axis is orthogonal to the cross-sectional plane. The off-axis angle α may be in a range from 2° to 8°. For example, the off-axis angle α may be 4°.

The gate structures 150 extend from the first surface 101 into the silicon carbide body 100 and include a gate dielectric 159 and a conductive gate electrode 155. The gate electrode 155 is electrically separated from the silicon carbide body 100. For example, the gate dielectric 159 may completely separate the gate electrode 155 from the silicon carbide body 100. According to other embodiments, one or more further dielectric structures with a material configuration different from the gate dielectric 159 and/or thicker than the gate dielectric 159 may be formed between the gate electrode 155 and the silicon carbide body 100.

A vertical extension of the gate structures 150 may be in a range from 0.3 μm to 5 μm, e.g., in a range from 0.5 μm to 2 μm. Sidewalls of the gate structures 150 may be vertical or may taper with increasing distance to the first surface 101. A width of the gate structures 150 in the plane of the first surface 101 may be in a range from 500 nm to 5 μm, e.g., in a range from 1 μm to 3 μm.

The gate structures 150 may taper with increasing distance to the first surface 101. For example, a taper angle of the gate structures 150 with respect to the vertical direction may be equal to the off-axis angle α or may deviate from the off-axis angle α by not more than ±1 degree such that at least a first mesa sidewall of two opposite longitudinal mesa sidewalls is formed by a main crystal plane with high charge carrier mobility, e.g., a {11-20} crystal plane. A second mesa sidewall opposite to the first mesa sidewall may be tilted to a main crystal plane by twice the off-axis angle α, e.g., by 4 degree or more, for example, by about 8 degrees. The first and second mesa sidewalls are on opposite longitudinal sides of the intermediate semiconductor mesa 170 and directly adjoin two different, neighboring gate structures 150.

According to other embodiments, the <0001> crystal axis may be tilted by the off-axis angle α to the surface normal 104 in a plane orthogonal to the cross-sectional plane. The <11-20> crystal axis may be tilted by the off-axis angle α with respect to the horizontal plane in the plane orthogonal to the cross-sectional plane. The <1-100> crystal axis may be horizontal and in the cross-sectional plane. The first and second mesa sidewalls may be vertical and parallel to a main crystal plane with comparatively high charge carrier mobility, e.g., the {1-100} crystal plane.

Body regions 120 and source regions 110 of the transistor cells TC are formed in semiconductor mesas 170, wherein the semiconductor mesas 170 are portions of the silicon carbide body 100 between neighboring gate structures 150. The source regions 110 are formed between the first surface 101 and the body regions 120. The body regions 120 are formed between the source regions 110 and the drift structure 130. The body regions 120 and the drift structure 130 form the first pn junctions pn1. The body regions 120 and the source regions 110 form second pn junctions pn2.

In each semiconductor mesa 170, a source region 110 and a body region 120 may directly adjoin a first sidewall 151 of a first one of two neighboring gate structures 150. A transistor shielding region 140 may directly adjoin a second sidewall 152 of a second one of the two neighboring gate structures 150. A vertical extension of the transistor shielding region 140 may be greater than a vertical extension of the gate structure 150.

The source metallization 310 may be in direct contact with the transistor shielding region 140 and with the source region 110. The body region 120 may be directly connected with the source metallization 310 or through the transistor shielding region 140.

The source metallization 310 may include an interface layer 318 and a source pad 319. A portion of an interlayer dielectric 210 between the source metallization 310 and the gate electrodes 155 may electrically separate the source metallization 310 and the gate electrodes 155 of the transistor cells TC.

According to the illustrated embodiment, the drift structure 130 may include current spread regions 139, wherein the current spread regions 139 are formed between neighboring transistor shielding regions 140. The current spread regions 139 and the body regions 120 may form the first pn junctions pn1. The current spread regions 139 may directly adjoin the first sidewalls 151 of the gate structures 150. A dopant concentration in the current spread regions 139 may be higher than in the drift zone 131 such that the current spread regions 139 may contribute to a more uniform distribution of the on-state current flow through the drift zone 131.

The transistor shielding region 140 may include a bottom portion 142 and a top portion 141, wherein the top portion 141 is between the first surface 101 and the bottom portion 142. A vertical dopant profile of the transistor shielding region 140 may include at least one local maximum. A distance between the first surface 101 and at least one of the local maxima may be greater than a vertical extension of the gate structures 150.

The shielding regions 440 in the gate pad region 730 may include a bottom portion 442 and a top portion 441, wherein the top portion 441 is between the first surface 101 and the bottom portion 442. A vertical extension of the top portions 441, 141 of the shielding regions 440 and the transistor shielding regions 140 may be equal. Vertical dopant profiles through the shielding regions 440 in the gate pad region 730 may correspond to vertical dopant profiles of the transistor shielding regions 140. The shielding regions 440 in the gate pad region 730 and the transistor shielding regions 140 in the transistor cell region 600 may be formed contemporaneously with the same implants.

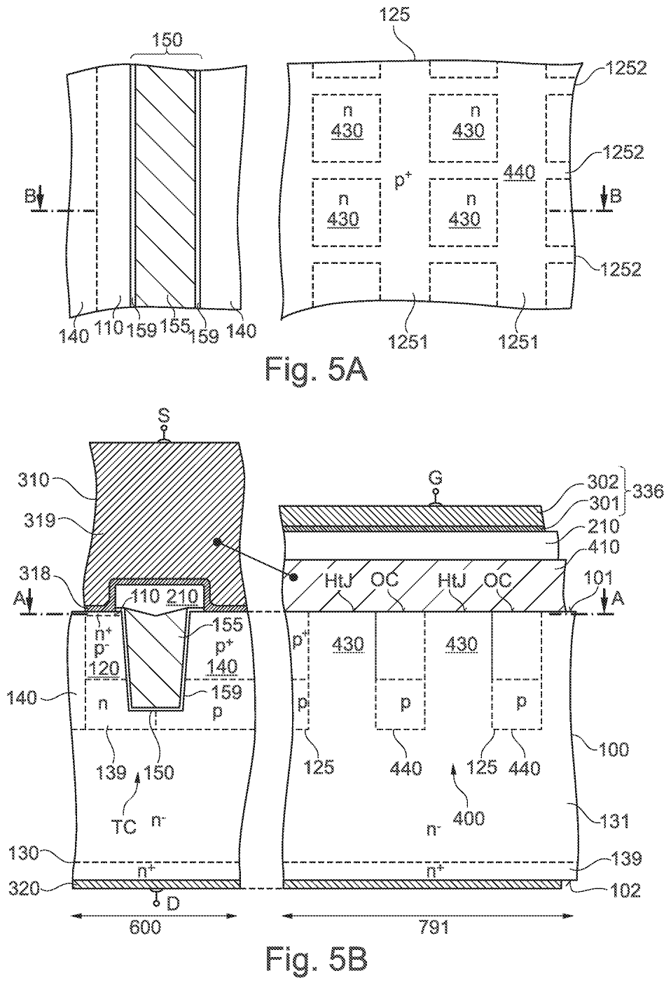

FIGS. 5A-5B illustrate a diode structure 400 including an MPH diode structure in an inner transition area 791 below a portion of a gate runner 336, wherein the illustrated portion of the gate runner 336 runs parallel to the transistor cells TC.

The inner transition area 791 may include a JTE (junction termination extension) 125. The JTE 125 has the conductivity type of the body regions 120 and may be in direct contact with the body regions 120 and/or with the transistor shielding regions 140 of the outermost transistor cells TC. A JTE 125 may include a more heavily doped inner portion and a more lightly doped outer portion.

A mean dopant concentration in the inner portion may be equal to a mean dopant concentration in the transistor shielding regions 140 or in the body regions 120. The mean dopant concentration in the outer portion may be lower than in the transistor shielding regions 140 and/or may be lower than in the body regions 120. A vertical extension of the JTE 125 may be equal to or smaller than a vertical extension of the transistor shielding regions 140.

The JTE 125 may include rail portions 1251 running parallel to the transistor cells TC and rung portions 1252. Each rung portion 1252 may extend between and may connect two neighboring rail portions 1251. Portions of the JTE 125 may be effective as the shielding regions 440 of the diode structures 400. Between the rung portions 1252 and the rail portions 1251, diode regions 430 extend through the JTE 125 and may form heterojunctions HtJ with a contact layer 410 electrically connected to the source metallization 310 as described with reference to FIGS. 3A to 3B. Portions of an interlayer dielectric 210 separate the gate runner 336 and the contact layer 410.

The gate runner 336 may be formed from portions of the first layer 301 and/or of the second layer 302 of the fine-patterned first portion of the front side metallization as described with reference to FIGS. 1A-2B.

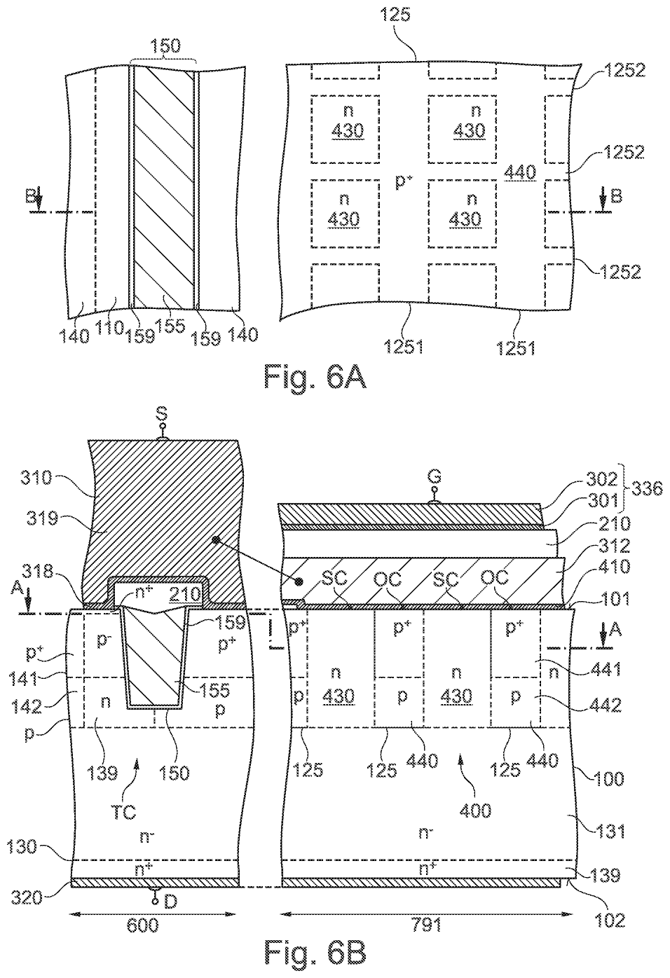

In FIGS. 6A-6B an MPS diode structure is formed in a portion of the inner transition area 791 in a vertical projection of the gate runner 336. The diode structure 400 may include diode regions 430 with a higher dopant concentration than the drift zone 131. The shielding regions 440 of the diode structure 400 may be formed using at least some of the implants performed for forming the transistor shielding regions 140 in the transistor cell region 600. A contact layer 410, which may include two sublayers as described with reference to FIGS. 2A-2B, may directly adjoin the first surface 101. A source connection structure 312 may be formed on the contact layer 410. The source connection structure 312 may be from polycrystalline silicon and may be electrically connected with the source metallization 310. A portion of an interlayer dielectric 210 may be between the gate runner 336 and the source connection structure 312.

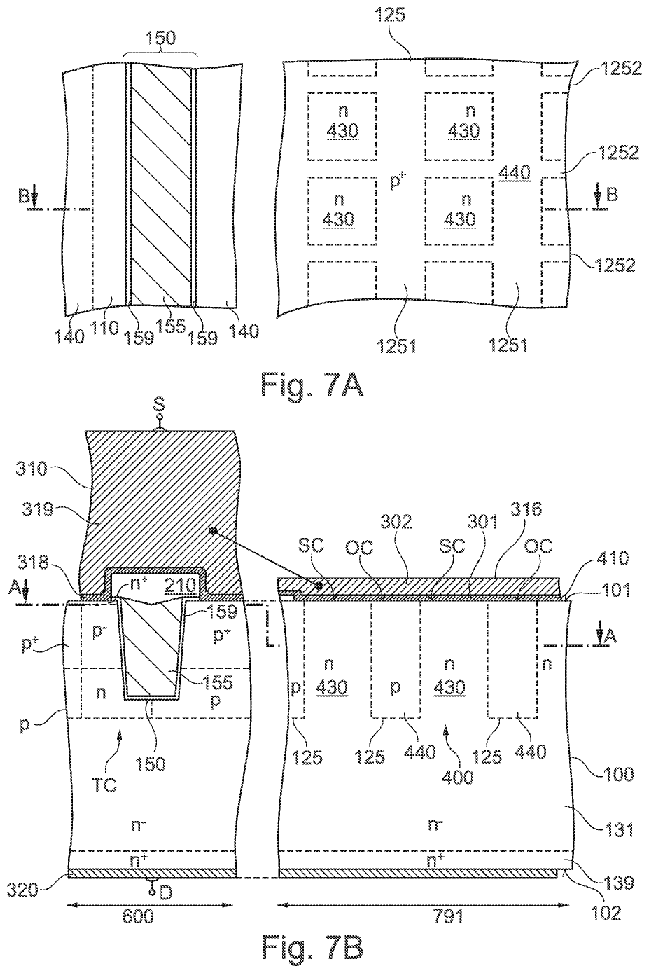

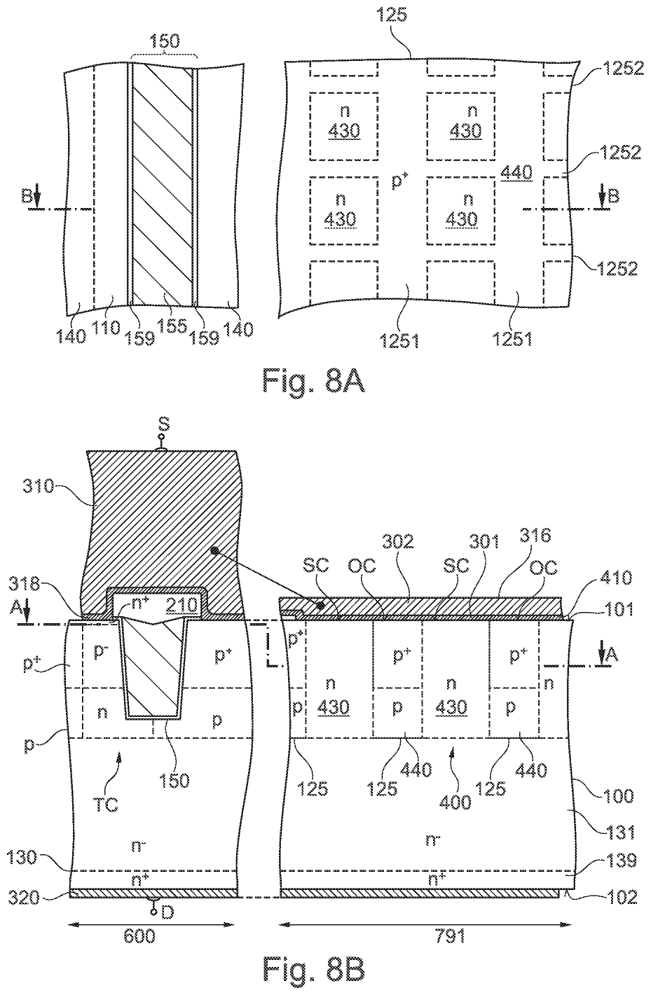

FIGS. 7A-8B refer to diode structures 400 in a portion of the inner transition area 791 directly below a source wiring line 316, e.g., directly below the lateral bulge 3161 of the source wiring line 316 as illustrated in FIG. 1A.

The source wiring line 316 may include a contact layer 410 directly on the first surface 101 and an auxiliary layer 315 electrically connected with the source metallization 310. The contact layer 410 may form Schottky contacts SC with the diode regions 430 and ohmic contacts OC with the shielding regions 440 of the diode structure 400. Portions of the JTE 125 may form shielding regions 440 of the diode structure 400.

The contact layer 410 may be formed from a portion of at least a first layer 301 of the fine-patterned portion of the front side metallization as described with reference to FIGS. 1A-2B. In addition the source wiring line 316 may include a portion of the second layer 302 of the fine-patterned first portion of the front side metallization as described with reference to FIGS. 1A-2B.

In FIGS. 7A and 7B the diode regions 430 may have the same dopant concentration as the drift zone 131 and the shielding regions 440 of the diode structure 400 may be homogeneously doped.

In FIGS. 8A and 8B, the diode regions 430 may be more heavily doped than the drift zone 131 and/or the shielding regions 440 of the diode structure 400 may have a vertical dopant profile with more than one local maximum.

For example, a dopant concentration in the diode regions 430 of the diode structure 400 may be equal to a dopant concentration in the current spread regions 139. Current spread regions 139 and diode regions 430 may share a common implant process.

A vertical dopant profile of the shielding regions 440 of the diode structure 400 may be similar or equal to a vertical dopant profile of the transistor shielding regions 140. Transistor shielding regions 140 and shielding regions 440 may share a common implant process.

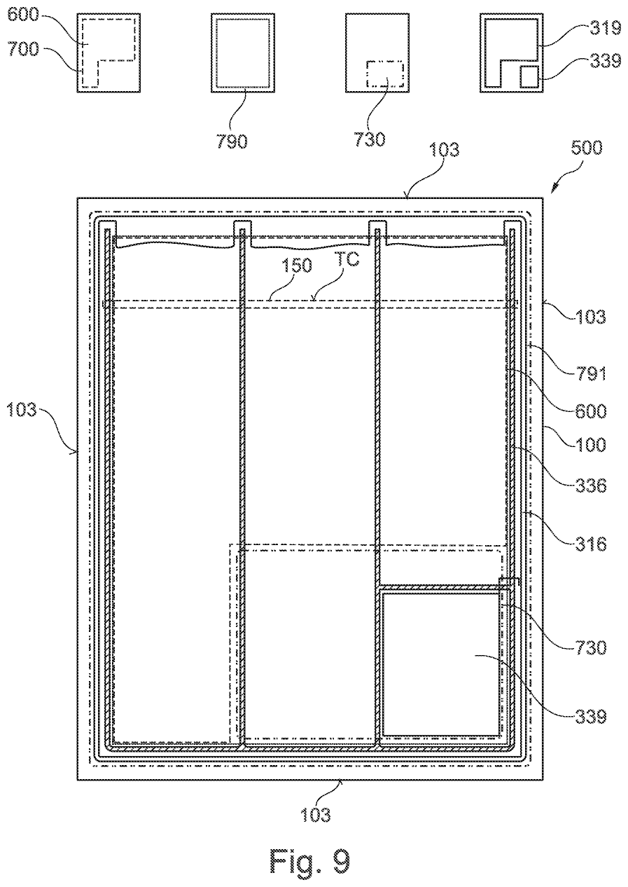

FIG. 9 shows a semiconductor device 500 with a gate pad region 730 significantly greater than a vertical projection of a gate pad 339 into the silicon carbide body 100. A vertical projection of a source pad 319 into the silicon carbide body 100 may mainly correspond to a transistor cell region 600. A comparatively wide gap between the gate pad 339 and the source pad 319 may facilitate alternatives to wire bonding.

For example, metal clips with a cross-sectional area significantly greater than a cross-sectional area of a bond wire may connect the source pad 319 and a source terminal and/or the gate pad 339 and a gate terminal. The metal clips may be sintered onto a top surface of the source pad 319 and/or onto a top surface of the gate pad 339. The comparatively wide distance between gate pad 339 and source pad 319 facilitates an economic sintering process for connecting the metal clips with the source pad 319 and/or the gate pad 339.

Typically, no transistor cells are formed too far outside a vertical projection of the source pad 319, because in case of a high load current, e.g., under short-circuit condition, a thermal stress in and around such transistor cells may be excessive. Since the MPS/MHS diode structures 400 conduct current for comparatively short periods of time, the portion of the silicon carbide body 100 below the gap between the source pad 319 and the gate pad 339 can be used for the MPS/MHS diode structures 400.

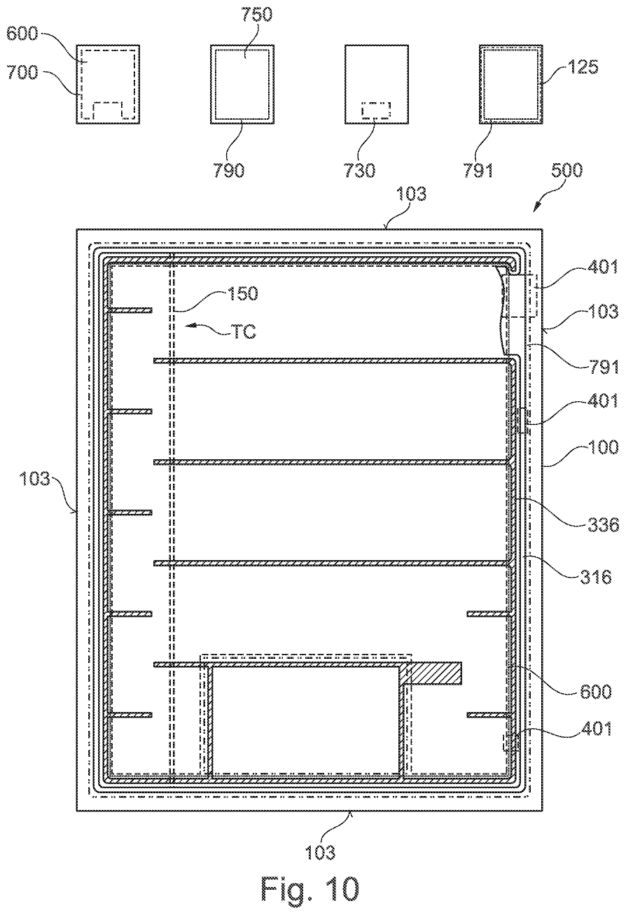

FIG. 10 shows junction structures 401, wherein doped regions of the junction structures 401 are formed in a transition region 790 of a silicon carbide body 100. The junction structures 401 may include heterojunctions and/or Schottky contacts. For further details, reference is made to the description of the previous figures.

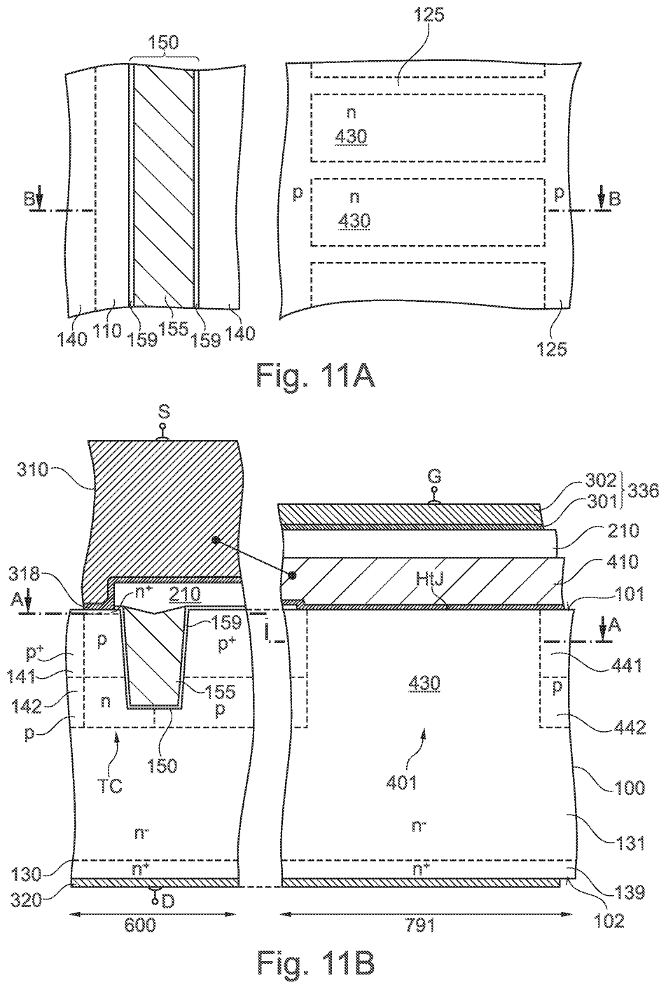

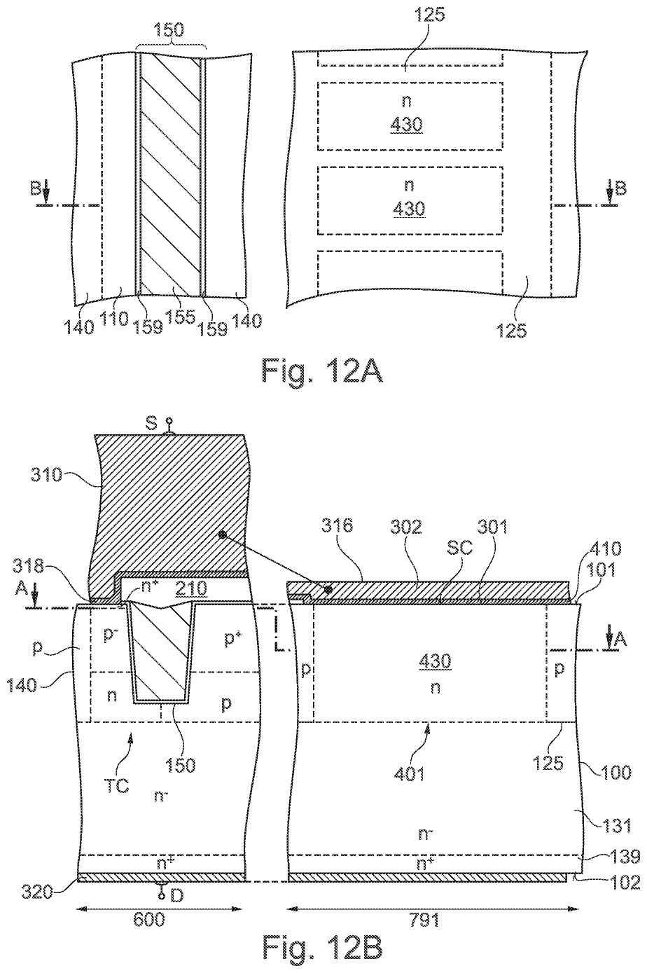

FIGS. 11A to 12B may differ from the embodiments described with reference to FIGS. 5A to 8B in that junction structures 401 may replace the merged MPS/MPH diode structures 400. In case the junction structure 401 is formed below a gate runner 336, the junction structure 401 may be a Schottky junction or may be a heterojunction HtJ as illustrated in FIGS. 11A to 11B. In case the junction structure 401 is formed below a source wiring line 316, the junction structure 401 may be a Schottky contact SC as illustrated in FIGS. 12A to 12B.

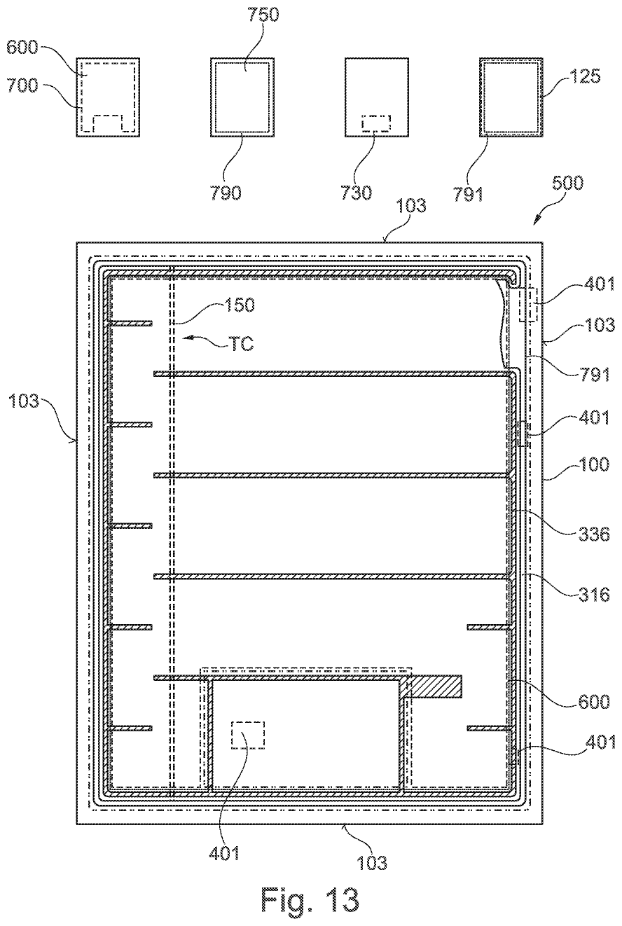

FIG. 13 shows another semiconductor device 500 with junction structures 401, wherein doped regions of the junction structures 401 may be formed in a transition region 790 and/or in a gate pad region 730 of a silicon carbide body 100. The junction structures 401 may include heterojunctions and/or Schottky contacts. For further details, reference is made to the description of the previous figures.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor device, comprising:
a silicon carbide body comprising a transistor cell region and an idle region, wherein
the transistor cell region comprises transistor cells, and
the idle region is devoid of transistor cells and comprises:
a transition region between the transistor cell region and a side surface of the silicon carbide body,
a gate pad region, and
a diode structure comprising at least one of a merged pin Schottky diode structure or a merged pin heterojunction diode structure in at least one of the transition region or the gate pad region.

2. The semiconductor device according to claim 1, comprising:
a contact layer formed on a first surface of the silicon carbide body, wherein the diode structure comprises a doped diode region and a shielding region, wherein the shielding region and the doped diode region form a pn junction, the contact layer and the doped diode region form a Schottky contact or a heterojunction, and the contact layer and the shielding region form an ohmic contact.

3. The semiconductor device according to claim 1, wherein the diode structure is formed in the gate pad region.

4. The semiconductor device according to claim 1, comprising:
a junction termination region surrounding the transistor cell region, wherein a lateral extension of the junction termination region defines an inner transition area of the transition region and wherein the diode structure is formed in the inner transition area.

5. The semiconductor device according to claim 4, wherein
the junction termination region includes rail portions and rung portions, wherein the rail portions surround the transistor cell region and the rung portions connect neighboring rail portions.

6. The semiconductor device according to claim 4, comprising:
a gate wiring line formed on a first surface of the silicon carbide body in the inner transition area, and
an interlayer dielectric separating the gate wiring line and the diode structure.

7. The semiconductor device according to claim 4, comprising:
a source wiring line formed on a first surface of the silicon carbide body in the inner transition area.

8. A semiconductor device, comprising:
a silicon carbide body comprising a central region and a transition region, wherein
the central region comprises a transistor cell region and a gate pad region, and the transistor cell region comprises transistor cells, and
the transition region is devoid of transistor cells, is positioned between the central region and a side surface of the silicon carbide body, and comprises a junction structure comprising a Schottky contact or a hetero junction.

9. The semiconductor device according to claim 8, comprising:
a contact layer formed on a first surface of the silicon carbide body.

10. The semiconductor device according to claim 8, comprising:
a junction termination region surrounding the central region, wherein a lateral extension of the junction termination region defines an inner transition area.

11. The semiconductor device according to claim 10, wherein
the junction structure is formed in the inner transition area.

12. The semiconductor device according to claim 11, comprising:
a gate wiring line formed on a first surface of the silicon carbide body in the inner transition area.

13. The semiconductor device according to claim 12, comprising:
an interlayer dielectric formed between the gate wiring line and the junction structure.

14. The semiconductor device according to claim 8, comprising:
a source wiring line formed on a first surface of the silicon carbide body in an inner transition area of the transition region.

15. The semiconductor device according to claim 14, wherein
a portion of the source wiring line forms a contact layer of the junction structure.

16. A semiconductor device, comprising:
a silicon carbide body comprising a transistor cell region and an idle region, wherein
the transistor cell region comprises transistor cells, and
the idle region is devoid of transistor cells and comprises:
a transition region between the transistor cell region and a side surface of the silicon carbide body,
a gate pad region, and
a junction structure in at least one of the transition region or the gate pad region, wherein the junction structure comprises a Schottky contact or a heterojunction.

17. The semiconductor device according to claim 16, wherein
the junction structure is positioned in the transition region.

18. The semiconductor device according to claim 16, wherein
the junction structure is positioned in the gate pad region.

19. The semiconductor device according to claim 16, wherein
the junction structure comprises the heterojunction.

20. The semiconductor device according to claim 16, wherein
the junction structure comprises the Schottky contact.
